(19) United States
(12) Patent Application Publication
(10) Pub. No.: US 2007/0080364 A1
(43) Pub. Date: Apr. 12, 2007

(54) White light emitting device capable of adjusting color temperature

(76) Inventor: Bear Hsiung, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/244,226

(22) Filed: Oct. 6, 2005

(51) Int. Cl. H01L 29/24

(52) U.S. Cl. 257/100

(57) ABSTRACT

A white light emitting device includes a first light emitting device, a photoluminescent phosphor, a second light emitting device, and a current adjuster. The first light emitting device has a light emitting layer made of semiconductor, and emits blue light. The photoluminescent phosphor completely absorbs light emitted by the first light emitting device to emit green light. The green light combines with the blue light to form cyan light. The second light emitting device has a light emitting layer made of semiconductor, and emits red light. The red light combines with the cyan light to form white light. The current adjuster is electrically connected to the second light emitting device to adjust the magnitude of the current transmitted to the second light emitting device, thereby controlling color temperature.

### BACKGROUND OF THE INVENTION

1. Field of the Invention

The present invention relates to a white light emitting device capable of adjusting color temperature and, more particularly, to a white light emitting device with the function of adjusting color temperature, which can be used as a white LED.

2. Description of Related Art

Because of the power-saving characteristics of low current and low drive voltage, LEDs, especially white LEDs, have attracted much attention in recent years.

There are many methods of fabricating white LEDs. For example, the Nichia company of Japan makes use of a single-die blue LED and the yellow emitting YAG phosphor coated thereon to produce white light, which is formed by combining yellow light generated when the phosphor is excited with the original blue light for excitation. FIG. 1 is a diagram showing the excitation spectrum of a blue LED and the emission spectrum of YAG phosphor in the prior art.

The above method, however, exists several severe problems. The first is the problem of uniformity. Because the single-die blue LED for exciting the yellow emitting phosphor participates in the generation of white light, the wavelength shift, the brightness variation of the single-die blue LED and the thickness of coated phosphor will affect the uniformity of white light. FIG. 2 is a chromaticity diagram of a white LED in the prior art. As shown in the figure, when the intersection position of the end of the straight line representing yellow light and the curve is shifted, the straight line passing the white light region will produce an evident shift to deflect the color temperature toward a colder or warmer region. This phenomenon causes problems in the production and application of white light. Besides, this method has also the problems of high color temperature of white light and low color rendering.

The Lumileds company of USA makes use of a blue LED to excite green emitting phosphor and red emitting phosphor to produce green light and red light, which combines with the original blue light for excitation to produce white light.

The disadvantage of the above method is that the red emitting phosphor has a low efficiency. In order to increase its efficiency, high-percentage and more red emitting phosphor is required, which results in reduction of brightness.

For the above methods of fabricating a white LED, because the wavelength of blue light and the thickness of phosphor will affect the color temperature, the problems of inconsistent color temperature and difficult control will arise. Some products produce white light with a colder color temperature, while some produce white light with a warmer color temperature, thus causing the problem of inconsistent products when processing mass production.

Accordingly, the conventional white LEDs have inconvenience and drawbacks in practical production and control. The present invention aims to propose a white light emitting device capable of adjusting color temperature to solve the above problems in the prior art.

### SUMMARY OF THE INVENTION

An object of the present invention is to provide a white light emitting device capable of adjusting color temperature, which can be used as a white LED to apply to different situations through adjustment of color temperature. The white light emitting device capable of adjusting color temperature will have a more stable shift of color temperature with a smaller variation as compared to the prior art.

To achieve the above object, the present invention provides a white light emitting device capable of adjusting color temperature, which comprises a first light emitting device, a photoluminescent phosphor, a second light emitting device, and a current adjuster. The first light emitting device has a light emitting layer made of semiconductor, and emits blue light. The photoluminescent phosphor completely absorbs light emitted by the first light emitting device to emit green light. The green light combines with the blue light to form cyan light. The second light emitting device has a light emitting layer made of semiconductor, and emits red light. The red light combines with the cyan light to form white light. The current adjuster is electrically connected to the second light emitting device to adjust the magnitude of the current transmitted to the second light emitting device.

To achieve the above object, the present invention also provides a white LED capable of adjusting color temperature, which comprises a metal reflection cup having a bottom, a blue LED chip adhered onto the bottom of the metal reflection cup, a photoluminescent phosphor covered on the blue LED chip to absorb blue light and then emit green light, a red LED chip adhered onto the bottom of the metal reflection cup and located at one side of the blue LED chip, a current adjuster electrically connected to the red LED chip to adjust the magnitude of the current transmitted to the red LED chip, and an encapsulant covered on the blue LED chip and the red LED chip.

### BRIEF DESCRIPTION OF THE DRAWINGS

The various objects and advantages of the present invention will be more readily understood from the following detailed description when read in conjunction with the appended drawing, in which:

FIG. 1 is a diagram showing the excitation spectrum of a blue LED and the emission spectrum of YAG phosphor in the prior art;

FIG. 2 is a chromaticity diagram of a white LED in the prior art;

FIG. 3 is a diagram of a white LED capable of adjusting color temperature of the present invention;

FIG. 4 is an equivalent diagram of a white LED capable of adjusting color temperature of the present invention;

FIG. 5 is a diagram of a white LED capable of adjusting color temperature according to a second embodiment of the present invention;

FIG. 6 is a diagram of a white LED capable of adjusting color temperature according to a third embodiment of the present invention;

FIG. 7 is a diagram of a white LED capable of adjusting color temperature according to a fourth embodiment of the present invention;

FIG. 8 is a diagram showing the excitation spectrum and emission spectrum of a white LED capable of adjusting color temperature of the present invention; and

FIG. 9 is a chromaticity diagram of a white LED capable of adjusting color temperature of the present invention.

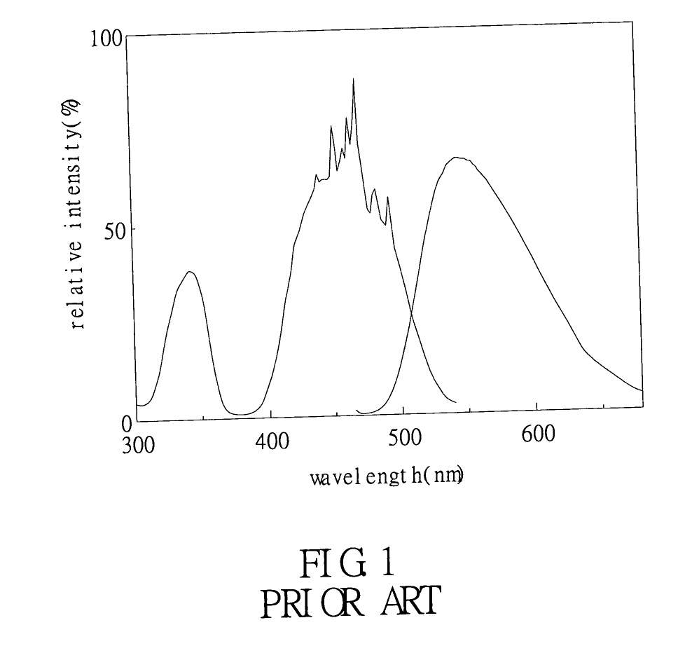

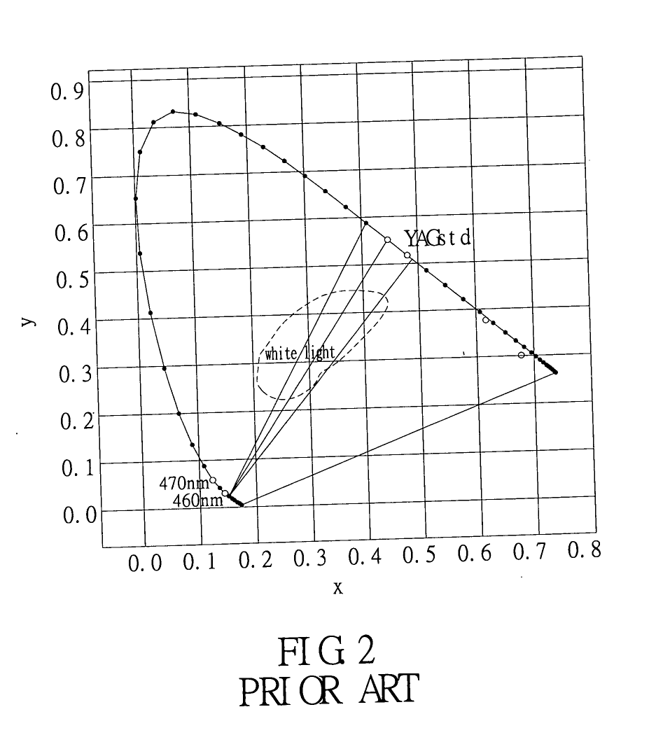

### DETAILED DESCRIPTION OF THE PREFERRED EMBODIMENTS

The present invention provides a white light emitting device capable of adjusting color temperature, which comprises a first light emitting device, a photoluminescent phosphor, a second light emitting device, and a current adjuster. The first light emitting device has a light emitting layer made of semiconductor, and emits blue light. The photoluminescent phosphor completely absorbs light emitted by the first light emitting device to emit green light. The green light combines with the blue light to form cyan light. The second light emitting device has a light emitting layer made of semiconductor, and emits red light. The red light combines with the cyan light to form white light. The current adjuster is electrically connected to the second light emitting device to adjust the magnitude of the current transmitted to the second light emitting device. The object of adjusting color temperature can thus be accomplished.

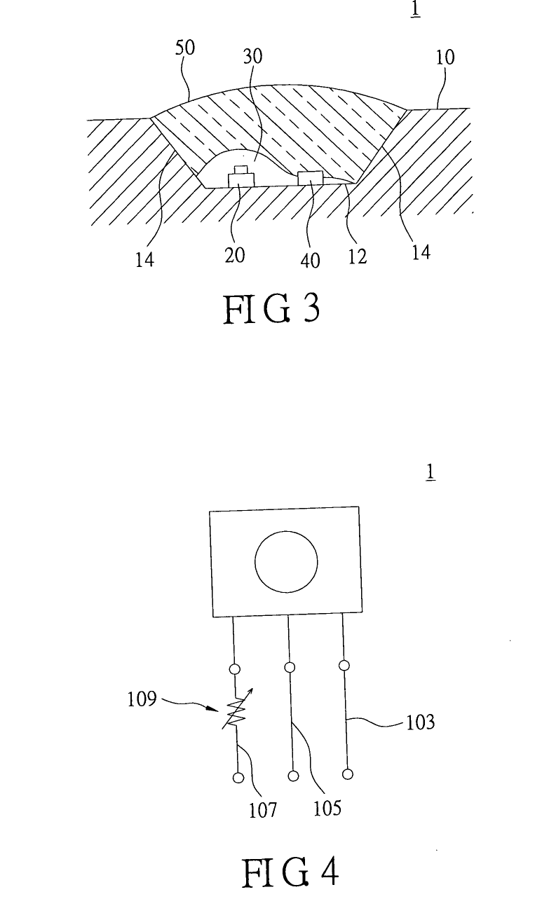

The white light emitting device capable of adjusting color temperature of the present invention can be used as an LED. As shown in FIG. 3, the present invention provides a white LED 1 capable of adjusting color temperature, which comprises a metal reflection cup 10, a blue LED chip 20, a photoluminescent phosphor 30, a red LED chip 40, and an encapsulant 50.

The metal reflection cup 10 is made of metal, and has a bottom 12 and a sidewall 14. The sidewall 14 is used to reflect and collect light.

The blue LED chip 20 is adhered onto the bottom 12 of the metal reflection cup 10. The blue LED chip 20 is preferred to be a high power LED chip.

The photoluminescent phosphor 30 covers on the blue LED chip 20 to absorb blue light, is excited by the blue light to emit green light. There are many kinds of photoluminescent phosphors that can emit green light after excited by blue light, e.g., (Zn,Cd)S:Cu,Al, (Zn,Cd)S:Cu, Zn₂GeO₄:Mn, ZnS:Cu,Au,Al, SrGa₂S₄:Eu. In the present invention, the photoluminescent phosphor 30 is preferred to be SrGa₂S₄:Eu.

The red LED chip 40 is adhered onto the bottom 12 of the metal reflection cup 10, and is located at one side of the blue LED chip 20.

The encapsulant 50 covers on the blue LED chip 20 and the red LED chip 40. The encapsulant 50 can be made of epoxy resin or other similar materials.

The present invention is primarily characterized in that the color temperature can be readily controlled by changing the energy provided for the red LED chip 40. The equivalent circuit diagram of the white LED capable of adjusting color temperature is shown in FIG. 4, in which there are two fixed power leads 103 and 105, and a current adjuster 109 is disposed on a power lead 107 capable of adjusting resistance. The current adjuster 109 (e.g., a variable resistor) is electrically connected to the red LED chip 40 to adjust the magnitude of the current transmitted to the red LED chip 40, thereby changing the intensity of red light to change the color temperature after color mixing. The object of adjusting color temperature of the present invention can thus be accomplished.

In the embodiment shown in FIG. 3, the bottom 12 of the metal reflection cup 10 is flat. In practical fabrication, phosphor usually covers on the chip in the form of fluid. When the photoluminescent phosphor 30 covers on the blue LED chip 20, it may overflow to the red LED chip 40 to also cover the red LED chip 40. In order to avoid this situation, the present invention also provides several embodiments illustrated below.

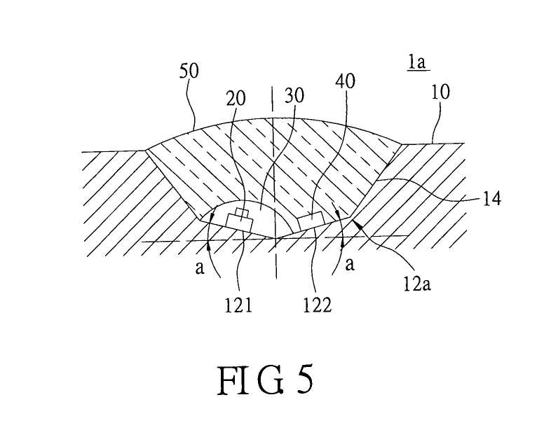

FIG. 5 is a diagram of a white LED capable of adjusting color temperature according to a second embodiment of the present invention, in which a white LED 1a is provided. A bottom 12a of the metal reflection cup 10 is composed of a pair of inclined planes 121 and 122. This pair of inclined planes 121 and 122 extend slantwise from the center to two sides of the bottom 12a, and are at an angle a with the horizontal plane so that the blue LED chip 20 and the red LED chip 40 can be disposed thereon.

This embodiment exploits the inclined bottom 12a so that the photoluminescent phosphor 30 won't overflow and cover on the red LED chip 40, thus ensuring the yield of product.

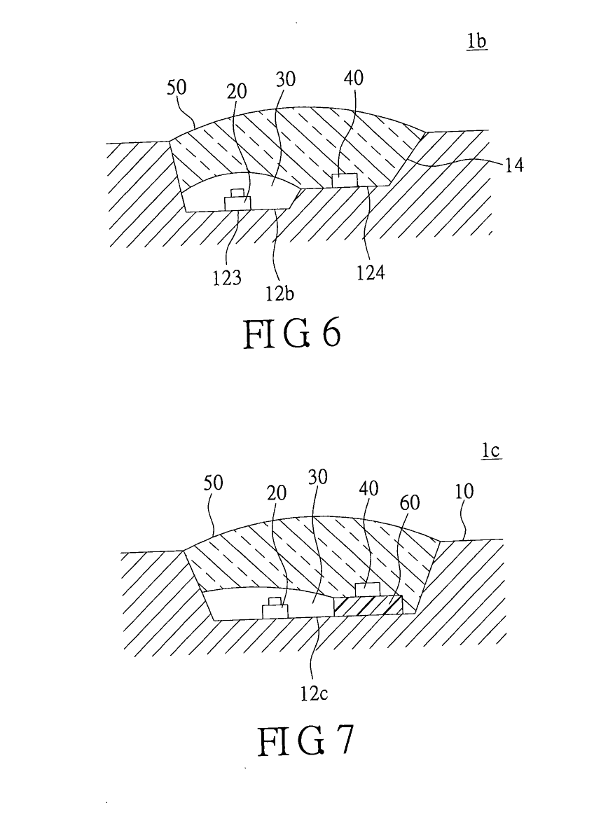

FIG. 6 is a diagram of a white LED capable of adjusting color temperature according to a third embodiment of the present invention, in which a white LED 1b is provided. A bottom 12b of the metal reflection cup 10 is stepped, and has a low-lying portion 123 and a prominent portion 124. The blue LED chip is disposed on the low-lying portion 123, and the red LED chip 124 is disposed on the prominent portion 124.

This embodiment exploits the height drop of the bottom 12b so that the photoluminescent phosphor 30 won't overflow and cover on the red LED chip 40, thus ensuring the yield of product. Moreover, the LED chips can be more easily disposed on the top faces of the low-lying portion 123 and the prominent portion 124.

FIG. 7 is a diagram of a white LED capable of adjusting color temperature according to a fourth embodiment of the present invention, in which a white LED Ic is provided. A bottom 12c of the metal reflection cup 10 is flat. An insulating pad 60 is fixed on the bottom 12c. The red LED chip 40 is adhered onto the insulating pad 60. The insulating pad 60 is made of insulating material such as silicon.

This embodiment exploits the height drop of the bottom 12c so that the photoluminescent phosphor 30 won't overflow and cover on the red LED chip 40.

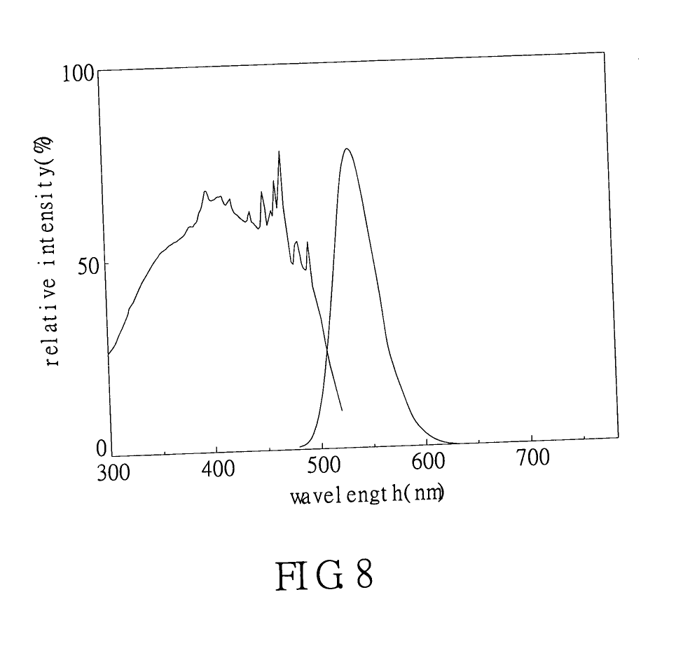

FIG. 8 is a diagram showing the excitation spectrum and emission spectrum of a white LED capable of adjusting color temperature of the present invention. The excitation spectrum at the left side shows a strong absorption band between 400 nm and 470 nm. The emission spectrum at the right side shows a wide band between 475 nm to 625 nm, with a center wavelength near 530 nm, meaning phosphor SrGa₂S₄:Eu is finely excited by blue light to emit green light.

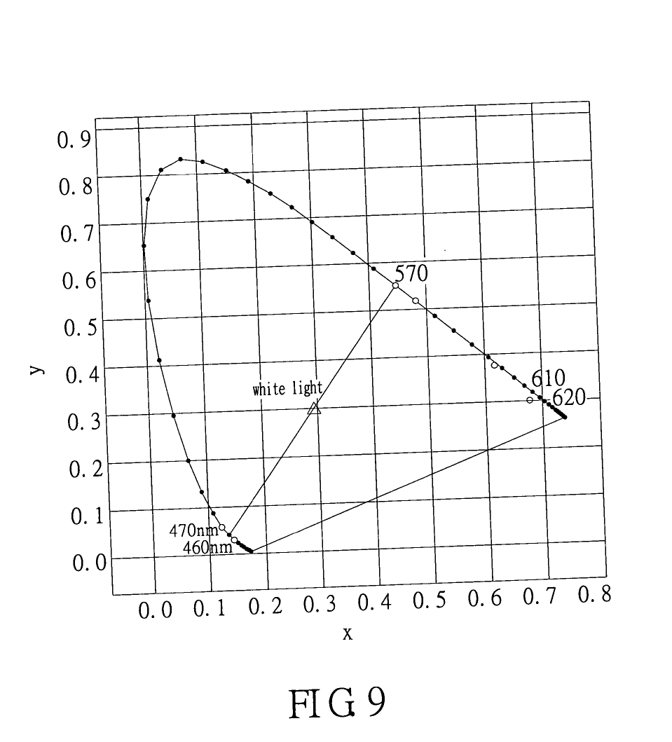

FIG. 9 is a chromaticity diagram of a white LED capable of adjusting color temperature of the present invention. As can be seen from this figure, white light of the present invention is formed by combining three lights with different wavelengths. Because of mutual dependence of these three lights, the present invention is characterized in a small shift of white light. As compared to the prior art, the present invention has a more stable shift of color temperature with a smaller variation, and has also a better color rendering.

Furthermore, the present invention can easily control the variation of color temperature of white light by changing the energy transmitted to the red LED. In other words, the present invention can flexibly adjust the color temperature of light to produce a pleasant atmosphere so as to meet the demands of different situations. For instance, light of low color temperature can be used to obtain a warm colored light suitable for use in home or hotel where people will feel easy and comfortable, or can be used to provide a soft white light suitable for use in office or school where people will feel lively. In hot regions, light of high color temperature can be used to get a cold and peaceful atmosphere.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

What is claimed is:

1. A white light emitting device capable of adjusting color temperature, comprising:
a first light emitting device having a light emitting layer made of semiconductor and emitting blue light;
a photoluminescent phosphor for completely absorbing light emitted by said first light emitting device to emit green light, said green light combining with said blue light to form cyan light;
a second light emitting device having a light emitting layer made of semiconductor and emitting red light, said red light combining with said cyan light to form white light; and
a current adjuster electrically connected to said second light emitting device to adjust the magnitude of a current transmitted to said second light emitting device.

2. The white light emitting device capable of adjusting color temperature as claimed in claim 1, wherein said photoluminescent phosphor is chosen among (Zn,Cd)S:Cu,Al, (Zn,Cd)S:Cu, Zn2GeO4:Mn, ZnS:Cu,Au,Al, SrGa₂S₄:Eu.

3. A white LED capable of adjusting color temperature, comprising:
a metal reflection cup having a bottom;
a blue LED chip adhered onto said bottom of said metal reflection cup;
a photoluminescent phosphor covered on said blue LED chip to absorb blue light and then emit green light;
a red LED chip adhered onto said bottom of said metal reflection cup and located at one side of said blue LED chip;
a current adjuster electrically connected to said red LED chip to adjust the magnitude of a current transmitted to said red LED chip; and
an encapsulant covered on said blue LED chip and said red LED chip.

4. The white LED capable of adjusting color temperature as claimed in claim 3, wherein said bottom of said metal reflection cup is flat.

5. The white LED capable of adjusting color temperature as claimed in claim 4, further comprising an insulating pad, wherein said insulating pad is disposed on said bottom of said metal reflection cup, and said red LED chip is adhered onto said insulating pad.

6. The white LED capable of adjusting color temperature as claimed in claim 3, wherein said bottom of said metal reflection cup extends slantwise from a center toward two sides thereof to form two inclined planes, and said blue LED chip and said red LED chip are respectively disposed on said two inclined planes.

7. The white LED capable of adjusting color temperature as claimed in claim 3, wherein said bottom of said metal reflection cup is stepped and has a prominent portion and a low-lying portion, said blue LED chip is disposed on said low-lying portion, and said red LED chip is disposed on said prominent portion.

8. The white LED capable of adjusting color temperature as claimed in claim 3, wherein said encapsulant is epoxy resin.

9. The white LED capable of adjusting color temperature as claimed in claim 3, wherein said current adjuster is a variable resistor.

10. The white LED capable of adjusting color temperature as claimed in claim 3, wherein said photoluminescent phosphor is chosen among (Zn,Cd)S:Cu,Al, (Zn,Cd)S:Cu, Zn₂GeO₄:Mn, ZnS:Cu,Au,Al, SrGa₂S₄:Eu.
